(19) United States
(12) Patent Application Publication
(10) Pub. No.: US 2005/0121786 A1
(43) Pub. Date: Jun. 9, 2005

(54) Semiconductor device and its manufacturing method

(75) Inventors: Akira Furuya, Kanagawa (JP); Nobuyuki Ohtsuka, Kanagawa (JP); Shinichi Ogawa, Osaka (JP); Hiroshi Okamura, Yamagata (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Semiconductor Leading Edge Technologies, Inc., Tsukuba-shi (JP)

(21) Appl. No.: 10/979,326

(22) Filed: Nov. 3, 2004

(30) Foreign Application Priority Data
Nov. 6, 2003 (JP) 2003-376685

(51) Int. Cl. H01L 21/00; H01L 21/4763; H01L 23/48; H01L 29/40

(52) U.S. Cl. 257/751; 257/758; 257/762; 438/643; 438/623; 438/687

(57) ABSTRACT

A semiconductor device comprises a semiconductor substrate and an interlayer interconnection structure provided on the semiconductor substrate. The interlayer interconnection structure includes a porous insulation film and a conductive part of a conductive material containing a metal as a major component. A volume occupation ratio of pores of a diameter greater than 0.6 nanometers is less than 30% in the porous insulation film.

### CROSS-REFERENCE TO RELATED APPLICATIONS

This application is based upon and claims the benefit of priority from the prior Japanese Patent Application No. 2003-376685, filed on Nov. 6, 2003; the entire contents of which are incorporated herein by reference.

### BACKGROUND OF THE INVENTION

The present invention relates to a semiconductor device and its manufacturing method, and more specifically, relates to a semiconductor device having interlayer insulation film with copper interconnection, and its manufacturing method.

In latest semiconductor devices represented by the 65-nanometer process technology node, device operation is restricted by signal delay in the interconnection. The delay constant in the interconnection is defined by a product of an interconnection resistance and a parasitic capacitance between interconnections. Therefore, in order to obtain a high speed device by reducing an interconnection resistance, the material having a lower relative dielectric constant than that of SiO₂ which is a conventional material (hereafter called “low dielectric constant material”) is being used as a material for the interlayer insulation film. And, Cu (copper) is being used as a material of the interconnection for its low specific resistance.

In many cases, copper multilayer interconnection is formed by a so-called damascene method.

FIGS. 14A through 14D illustrate process steps for explaining the principal part of the damascene processing. In FIG. 14A, an interlayer insulation film 220 consisting of low dielectric constant material is formed on a substrate 200 which is a silicon substrate, for example. In FIG. 14B, a hole H is provided in the interlayer insulation film 220. The hole H performs functions of the interconnection slot for interconnection layer, and a via hole for a via. In FIG. 14C, a barrier metal layer 240 is formed in an inner wall of the hole H. In FIG. 14D, a Cu layer 260 is embedded in the hole H as a material of the interconnection. In this step, embedment of the Cu layer 260 is performed by depositing Cu in a thin film fashion by physical vapor deposition method (PVD), for example, and embedding the Cu layer by electrolytic plating using the Cu thin film as a cathode electrode in many cases.

In the damascene processing, after depositing the barrier metal layer 240 and the Cu layer 260, a protrusion of the barrier metal layer 240 and the Cu layer 260 above the hole is flattened by the chemical mechanical polishing method (CMP). In this way, an embedded structure expressed in FIG. 14D is formed.

The barrier metal layer 240 has functions of preventing Cu from diffusing into the substrate 200 such as a silicon substrate, promoting an adhesion of the Cu layer 260 to the interlayer insulation film 220, and preventing the Cu layer 260 from oxidizing.

The interconnection layer structure using the interlayer insulation film consisting of low dielectric constant material above-explained is disclosed by K. Maex, M. R. Baklanov, D. Shamiryan, F. Iacopi, S. H. Brongersma, Z. S. Yanovitskaya, Journel of Applied Physics 93 (11), pp. 8793-8841, 2003, and by W. Besling, A. Satta, J. Schuhmacher, T. Abell, V. Sutcliffe, A.-M. Hoyas, G. Beyer, D. Gravesteijn, K. Maex, Processings of IEEE 2002 International Technology Conference, pp. 288-291.

A porous insulating material is the most hopeful material of a low dielectric material for the interlayer insulation film 220. However, in the case of forming Cu multilayer interconnection layer structure using the porous insulating material, there has been a problem that the barrier metal materials and Cu penetrate pores of the porous insulating material in a deposition process of the barrier metal or a deposition process of Cu. If the barrier metal penetrates the pores of the porous insulating material, the thickness of the barrier metal becomes thinner. Consequently, since the ability of preventing Cu from diffusing which the barrier metal should have degrades, reliability of, such as a transistor, falls. An insulating characteristic such as withstand voltage of the insulator also degrades because of metals such as the barrier metal and Cu penetrating the pores. And the current leak between adjacent interconnections occurs and the reliability of the signal propagation in interconnection falls.

Recently, it has been considered to reduce interconnection resistance and a via resistance by making the barrier metal into a thinner film. However, by the current PVD method mainly used, since the thickness of the barrier metal on sidewalls of a interconnection slot and a via hole is sufficiently thin at present, it is impossible to insure higher characteristic of the barrier ability and adhesion ability in the thinner barrier metal. Then, it is required that the barrier metal is formed by chemical vapor deposition method (CVD) suitable for obtaining a thin film with excellent coverage. However, by the CVD method, since a thin film is deposited by a decomposition reaction on the substrate surface, the diffusion through the pores of the porous films tend to occur compared with by PVD method. Therefore, it is indispensable to prevent the diffusion through the pores on the side surfaces of the interconnection slot and the via hole of the porous interlayer insulation film in this case.

The method of depositing another insulating film and filling the pores after processing the interlayer insulation film is considered to prevent the diffusion of the metal. Moreover, in processing of the interlayer insulation film, the method of filling the hole which is open to a surfaces adjacent to the barrier metal by depositing the by-product generated during processing. This method is disclosed by K. Maex et. al., Journal of Applied Physics 93 (11), pp.8793-8841, 2003. However, in this method, there is a possibility that the dielectric constant may increase or a size of the pores may change by incorporating the new substance.

On the other hand, the method of filling the pores of porous material with the plasma treatment using N₂ plasma is examined. This method is disclosed by W. Besling et. al., Proceedings of IEEE 2002 International Interconnect Technology Conference, pp. 288-291. However, as a result of examining the effect of preventing diffusion by filling the pores with N₂ plasma treatment by Inventors, it became clear that an effect may be little and diffusion of the barrier metal or Cu may occur depending on the material of the interlayer insulation film. Furthermore, with N₂ plasma treatment, there is a possibility that a dielectric constant may become high by nitriding of the surface of the interlayer insulation film.

### SUMMARY OF THE INVENTION

According to an embodiment of the invention, there is provided a semiconductor device comprising a semiconductor device comprising: a semiconductor substrate; and an interlayer interconnection structure provided on the semiconductor substrate including: a porous insulation film in which a volume occupation ratio of pores of a diameter greater than 0.6 nanometers is less than 30%; and a conductive part of a conductive material containing a metal as a major component.

According to other embodiment of the invention, there is provided a method for manufacturing a semiconductor device comprising: forming a thin film containing a insulator material on a substrate; opening a hole in the thin film; and depositing a conductor material in the hole, wherein the forming the thin film includes forming the thin film in a porous fashion in which a volume occupation ratio of pores of a diameter greater than 0.6 nanometers is less than 30%, having: mixing a dielectric material and a pore generating material; coating the mixture of the dielectric material and the pore generating material on the substrate; drying the mixture; applying a heat treatment to the mixture.

According to other embodiment of the invention, there is provided a method for manufacturing a semiconductor device comprising: forming a thin film containing a insulator material on a substrate; opening a hole in the thin film; and depositing a conductor material in the hole wherein the forming the thin film includes forming the thin film in a porous fashion in which a volume occupation ratio of pores of a diameter greater than 0.6 nanometers is less than 30%, having: coating a dielectric material containing pores on the substrate; drying the dielectric material; applying a heat treatment to the dielectric material.

According to other embodiment of the invention, there is provided a method for manufacturing a semiconductor device comprising: forming a thin film containing a insulator material on a substrate; opening a hole in the thin film; and depositing a conductor material in the hole wherein the forming the thin film includes forming the thin film in a porous fashion in which a volume occupation ratio of pores of a diameter greater than 0.6 nanometers is less than 30%, having: generating plasma of a gas containing a source gas of a dielectric material; and decomposing the source gas by the plasma.

### BRIEF DESCRIPTION OF THE DRAWINGS

The present invention will be understood more fully from the detailed description given herebelow and from the accompanying drawings of the embodiments of the invention. However, the drawings are not intended to imply limitation of the invention to a specific embodiment, but are for explanation and understanding only.

In the drawings:

FIG. 1 is a schematic diagram illustrating a cross-sectional structure of a major part of a semiconductor device according to an embodiment of the invention;

FIG. 2 is a cross-sectional view showing the connection interface between the interlayer insulation film (P-MSQ) and the barrier metal layer (BM), and the connection interface between the barrier metal layer (BM) and the interconnection layer (Cu) as a comparative example;

FIG. 3 is a cross-sectional view showing the connection interface between the interlayer insulation film (P-MSQ) and the barrier metal layer (BM), and the connection interface between the barrier metal layer (BM) and the interconnection layer (Cu) as a comparative example;

FIG. 4 is an enlarged schematic cross-sectional view of the interface between the interlayer insulation film and the metal in the semiconductor device of the embodiment of the invention;

FIGS. 5A through 5C show process steps for manufacturing the semiconductor device according to the example of the invention;

FIGS. 6A and 6B show process steps for manufacturing the semiconductor device according to the example of the invention;

FIG. 7 is a schematic diagram illustrating a cross-sectional view of a semiconductor device examined by the Inventors as an experimental manufacture;

FIG. 8 is a schematic diagram illustrating the results of the cross-sectional observation about each sample by the line drawing;

FIGS. 9A through 9C are cross-sectional views showing the processes of manufacturing method according to the modified examples of the present invention;

FIGS. 10A and 10B are cross-sectional views showing the processes of manufacturing method according to the modified examples of the present invention;

FIG. 11 are cross-sectional views showing the processes of the manufacturing method according to the second modified example of the invention;

FIG. 12 is a schematic cross-sectional view illustrating a modified example of the semiconductor device according to the invention;

FIG. 13 is a schematic diagram illustrating the cross-sectional structure of an integrated circuit applied to the embodiment of the invention; and

FIG. 14A and FIG. 14B illustrate process steps for explaining the principal part of the damascene processing.

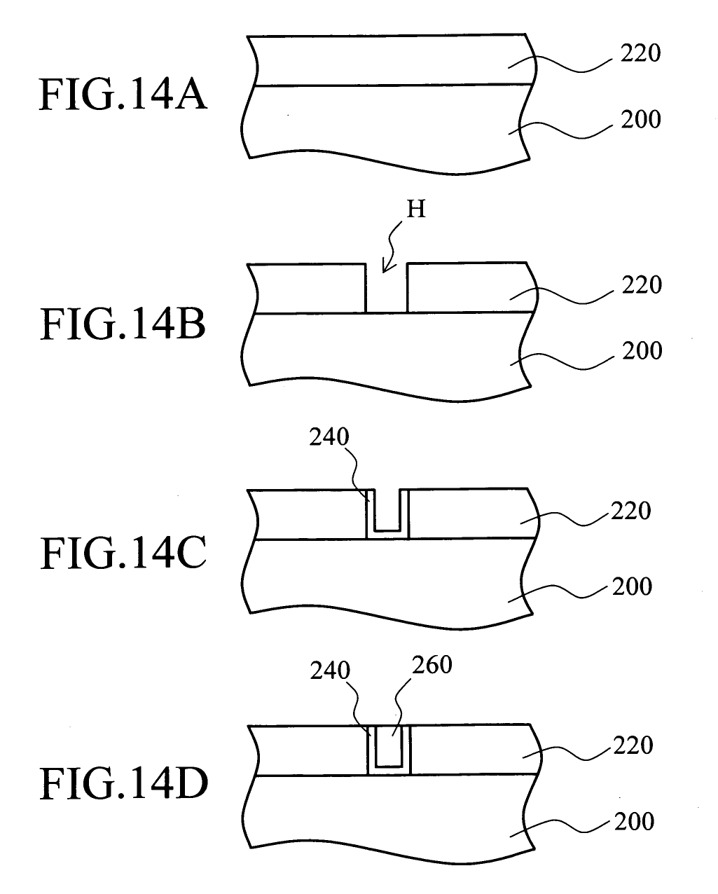

### DETAILED DESCRIPTION

Referring to drawings, some embodiments of the present invention will now be described in detail.

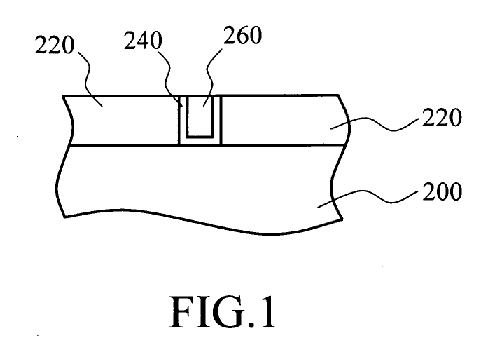

FIG. 1 is a schematic diagram illustrating a cross-sectional structure of a major part of a semiconductor device according to an embodiment of the invention. The semiconductor device of this embodiment has a substrate 200 and an interlayer interconnection structure provided on the substrate 200. The interlayer interconnection structure has interlayer insulation films of a low dielectric constant material, and embedded metals formed by the damascene process, for example. Thus, the interlayer insulation film 220 of a low dielectric constant material is provided on the semiconductor substrate 200 of silicon, for example, and a metal interconnection layer 260 is embedded in a via hole penetrating a part of the semiconductor substrate 200. A sidewall and bottom of the via hole are covered with a barrier metal layer 240. The metal interconnection layer 260 consisting of copper or copper alloy, for example, has a function as an electrode of semiconductor elements, such as a transistor provided on the substrate 200, and an interconnection layer embedded in the interlayer insulation film 220.

In this invention, porous and low dielectric constant material is used as a material of the interlayer insulation film 220. Further, porous and low dielectric constant material in which the volume occupation ratio of the pores having a diameter greater than 0.6 nanometers to total pores introduced in the material is less than 30% is used. By using the insulator having such a unique volume occupation ratio of the pores, metallic elements constituting the barrier metal layer 240 and the Cu layer 260 can be prevented effectively from diffusing into the interlayer insulation film 220.

Therefore, by making a dielectric porous include pores, the dielectric constant can be reduced efficiently. Subsequently, a parasitic capacitance can be reduced greatly. The Inventors made samples of metal-embedded structures as expressed in FIG. 1 by making dielectric thin films porous and investigated whether the barrier metal layer 240 diffuses into the interlayer insulation film 220 or not. As a result, it turned out that there is correlation between the porosity of the dielectric material constituting the interlayer insulation film 220 and the diffusion of the barrier metal layer 240. By further detailed investigation, it turned out that the diffusion of the barrier metal layer 240 can be effectively prevented, if the low dielectric constant material in which the volume occupation ratio of the pores having a diameter greater than 0.6 nanometers is less than 30 % is used.

The form of the pore contained in the low dielectric constant material is not necessarily spherical. The “diameter” of the pore in this specification means a diameter of a perfect circle having the same volume as the pore in cross-sectional observation or a diameter of a sphere having same volume as the pore stereoscopically. If the interlayer insulation film 220 is formed by such a low dielectric constant material of the embodiment, the diffusion of the barrier metal layer 240 can be suppressed effectively.

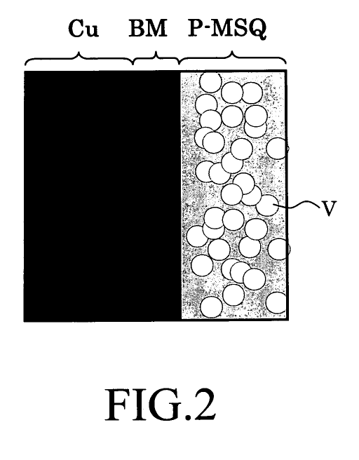

FIGS. 2 through 4 are schematic diagrams showing whether the diffusion of the low dielectric constant material occurs or not in comparative examples and the embodiment of the invention.

FIG. 2 is a cross-sectional view showing the connection interface between the interlayer insulation film (P-MSQ) and the barrier metal layer (BM), and the connection interface between the barrier metal layer (BM) and the interconnection layer (Cu) as a comparative example. As illustrated in this figure, the interlayer insulation film is made porous by introducing the pores V in order to lower the dielectric constant. In the interlayer insulation film, the porous film in which the volume occupation ratio of the pores having a diameter greater than 0.6 nanometers is higher than 30% is formed.

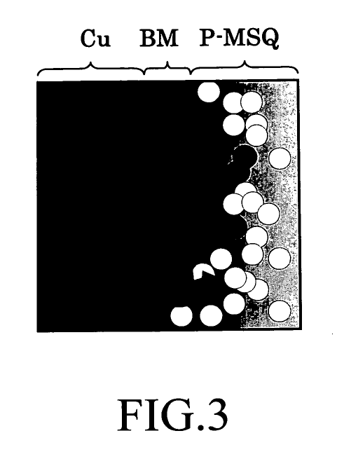

When above-mentioned porous interlayer insulation film (P-MSQ) having such volume occupation ratio of the pores touches with the barrier metal layer (BM), as shown in FIG. 3, the barrier metal diffuses into the interlayer insulation film (P-MSQ) through the pores V. It is considered that the diffusion occurs because effective paths for the diffusion of the barrier metal is formed in the interlayer insulation film (P-MSQ) owing to large size and large number of pores V. Such diffusion causes a thinner layer of the barrier metal layer (BM). Furthermore, continuous film layer cannot be preserved by such diffusion. Further, since the metal of the connection layer (Cu) also diffuses into the interlayer insulation film (P-MSQ) and the semiconductor substrate which is not illustrated, the reliability of a transistor falls, for example. Moreover, if metals, such as a barrier metal and Cu, penetrate the interlayer insulation film, for example, dielectric strength including withstand voltage of the interlayer insulation film (P-MSQ) also falls. Subsequently, since a current leak occurs between the adjacent interconnections, the reliability of the signal propagation through interconnections falls.

Such diffusion may occur simultaneously with the deposition process of the barrier metal layer (BM) by a chemical vapor deposition method (CVD), for example. Moreover, such diffusion may occur simultaneously with the heating process after depositing the barrier metal layer (BM).

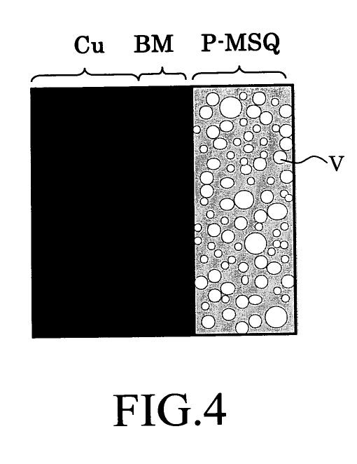

FIG. 4 is an enlarged schematic cross-sectional view of the interface between the interlayer insulation film and the metal in the semiconductor device of the embodiment of the invention. If the porous and low dielectric constant material in which the volume occupation ratio of the pores V having a diameter greater than 0.6 nanometers is less than 30% is used as a material for the interlayer insulation film (P-MSQ), the diffusion of the barrier metal through the pores V markedly reduces. In other words, because effective paths for the diffusion of the barrier metal in the interlayer insulation film (P-MSQ) reduce sharply, a substantial diffusion is suppressed. Consequently, since the diffusion of the barrier metal is suppressed also in the deposition process of the barrier metal, or a subsequent heat treatment process, the outstanding initial characteristic and reliability can be maintained.

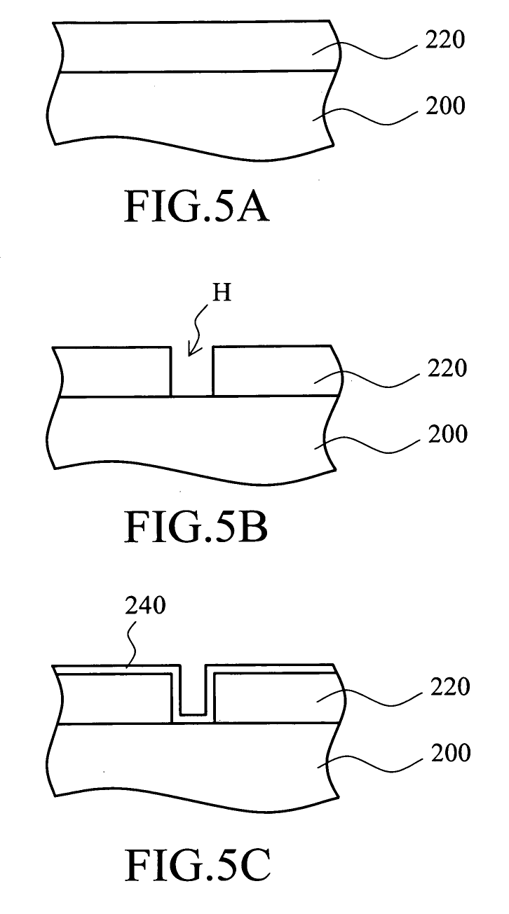

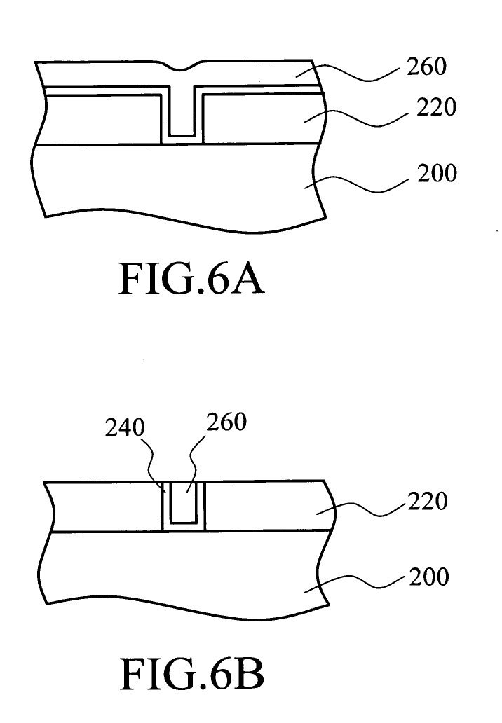

FIGS. 5A through 6B show process steps for manufacturing the semiconductor device according to the example of the invention. First, as expressed in FIG. 5A, the insulating film 220 is formed on the substrate 200, such as a silicon substrate. In this step, the insulating film 220 is formed in a porous fashion in which the volume occupation ratio of the pores V having a diameter greater than 0.6 nanometers is less than 30%. As a material of the insulating film 220, porous methyl silsequioxane (MSQ) can be used, for example.

The insulating film 220 can be formed by the spin on glass method (SOG) method which is a method of forming a thin film by spin coating of a solution and carrying out a heat-treatment, for example. Moreover, it can be also formed by the plasma chemical vapor deposition method (CVD).

In the case of the spin on glass method, the size and the number of the pores introduced into the interlayer insulation film can be controlled by the following two kinds of methods, for example.

(A) A pore generating material called “porogen” or a “template”, and a material containing the main ingredients of the interlayer insulation film are mixed, coated on the substrate 200 and dried. Then, they are dried and carried out heat-treatment for generating pores at the temperature of about 100 through 300 degrees Centigrade. Then, heat treatment for sintering is carried out at the temperature at about 300 through 500 degrees Centigrade, for example.

In this method, the size and the number of the pores introduced into the interlayer insulation film can be controlled by adjusting the kind and the concentration of the pore generating material, and the condition of forming pores of the materials for forming pores.

(B) A material containing pores inherently is used as a material containing the main ingredients of the interlayer insulation film, and it is coated on the substrate. Then, it is dried, and carried out heat-treatment at 300 through 500 degrees Centigrade, for example. In this method, the size and the number of the pores introduced into the interlayer insulation film can be controlled by adjusting the size and the number of the pores in the pore generating material, and conditions of the heat treatment for forming the pores.

On the other hand, the case of the plasma CVD method is as the following.

(C) A source gas containing the main ingredients of the interlayer insulation film, and other gas, such as argon (Ar), nitrogen (N₂), and helium (He), are introduced in a vacuum chamber. A low dielectric constant material can be deposited on the substrate 200. The plasma is generated from these gas. In this case, the size and the number of the pores introduced into the interlayer insulation film can be controlled by adjusting conditions, such as a kind of source gas, the gas flow ratio, substrate temperature, the power of plasma, deposition rate, and existence of bias voltage.

By the above-mentioned method, the porous interlayer insulation film 220 in which the volume occupation ratio of the pores having a diameter greater than 0.6 nanometers is less than 30% is formed. Next, in FIG. 5B, a hole H is formed in the interlayer insulation film 220. The hole H may be formed by forming a resist mask which is not illustrated, etching an exposed insulating film, and removing the resist mask by ashing.

In FIG. 5C, the barrier metal layer 240 is deposited. As a material of the barrier metal, tantalum nitride (TaN) can be used, for example. The barrier metal layer can be formed by the deposition methods, such as atomic layer deposition method (ALD), the atomic layer chemical vapor deposition method (ALCVD), or the CVD method, for example. Although PVD particles may be implanted into the interlayer insulation film 220 and may diffuse inside the interlayer insulation film 220 owing to their large energy, in the physical vapor deposition method (PVD), there is a possibility, a modified layer 220M can prevent such a diffusion into the film according to the embodiment of the invention.

Subsequently, in FIG. 6A, the interconnection layer 260 is deposited. As a material of the interconnection layer 260, Cu can be used, for example. In order to embed Cu inside the hole H, a thin film of Cu is firstly formed by the PVD method as mentioned above. Subsequently, Cu is embedded into the hole H by a plating process using this Cu thin film as a cathode electrode.

Then, by the CMP method, the interconnection layer 260 deposited on the surface of the insulating film 220, and the barrier metal layer 240 under the interconnection layer 260 are removed by polishing. Consequently, the embedded structure shown in FIG. 6B is completed.

According to the manufacturing method of the invention explained above, a diffusion of the barrier metal or the interconnection material (Cu) into the interlayer insulation film 220 can be prevented certainly and easily by forming the porous dielectric in which volume occupation ratio of the pores having a diameter greater than 0.6 nanometers is less than 30% as the interlayer insulation film 220.

The inventors investigated whether the metallic elements constituting the metal interconnection layer diffuse or not the changing the volume occupation ratio of the pores variously.

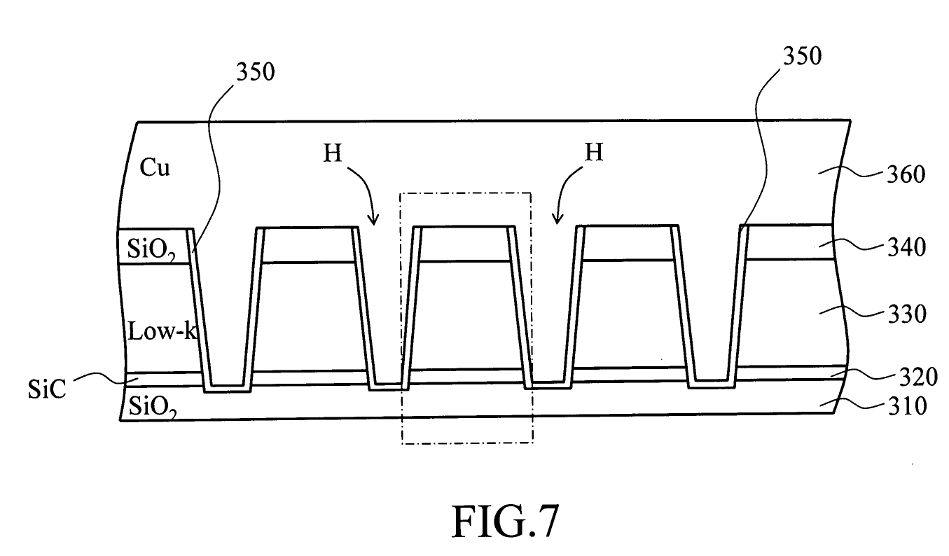

FIG. 7 is a schematic diagram illustrating a cross-sectional view of a semiconductor device examined by the Inventors as an experimental manufacture. The semiconductor device has the interlayer insulation layer in which a silicon dioxide (SiO₂) layer 310, a SiC hard mask layer 320, an interlayer insulation film 330 and a SiO₂ cap layer 340 are laminated in this order on the semiconductor substrate. The holes H are provided in the interlayer insulation layer. The barrier metal 350 and Cu 360 are embedded in the hole H. On the holes, interconnection layer will be formed. The “dual damascene” structure where Cu 360 is embedded in the interconnection and via holes is formed. Tantalum Nitride (TaN) is used as a material of the barrier metal 350.

In the examples of experimental manufacture, the interlayer insulation film 330 is made of MSQ, and formed by above-mentioned method (A) and (B), respectively. In each method, seven kinds of samples are manufactured respectively, by adjusting the conditions of the material and the heat treatment. The samples have seven kinds of volume occupation ratio of the pores having a diameter greater than 0.6 nanometers which are in the range between 0% and 54%. The diameter and volume occupation ratio of the pores are measured by the X-ray diffuse scattering method. The detail of the measurement method is described by K. Omote et al., “Small angle x-ray scattering for measuring pore-size distributions in porous low-k films”, Appl. Phys. Letters, Vol. 82, No. 4, pp. 544-546, January, 2003. In order to determine the size and the volume occupation ratio of the pores, the Inventors have employed a software called “Nano-Solver” provided by Rigaku Corporation to analyze the X-ray data.

Also, with regard to the samples of the experimental manufacture, cross-sectional observations by a transmission electron microscope (TEM) were performed. The existence of the diffusion of the metallic elements into the interlayer insulation film 330 was investigated by EDX (energy dispersive X-ray analysis).

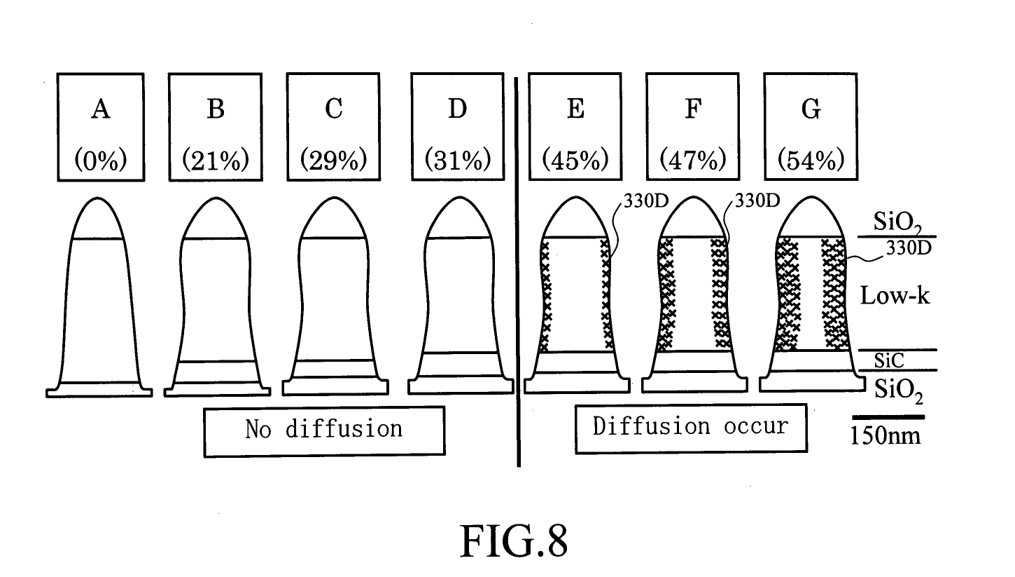

FIG. 8 is a schematic diagram illustrating the results of the cross-sectional observation about each sample by the line drawing. That is, FIG. 8 is an enlarged cross-sectional view of the portion surrounded by the dashed line in FIG. 7. FIG. 8 is a result of the sample manufactured by the manufacturing method (B). In these cross-sectional views, regions where the diffusions of the barrier metal 350 or the metallic element of Cu360 are observed are expressed with crossing figures. FIG. 8 shows that the metallic elements penetrate into a region of tens of nanometers from the interface on sidewalls of the interlayer insulation film 330 about the samples (E-G) in which the volume occupation ratios of the pores having a diameter greater than 0.6 nanometers are less than 45%. That is, it is found that diffusion of electrode material occurs. On the other hand, about the samples (A-D) in which the volume occupation ratios of the pores having a diameter greater than 0.6 nanometers are less than 31%, the metallic elements are not found in the interlayer insulation film 330. That is, it turns out that diffusions are controlled.

Table 1 provides a summary of the evaluation result about each sample.

TABLE 1

| | A | B | C | D | E | F | G |
|---|---|---|---|---|---|---|---|
| volume occupation | 0 | 21 | 29 | 31 | 45 | 47 | 54 |
| ratios of the pores | | | | | | | |
| having a diameter | | | | | | | |
| greater than 0.6 | | | | | | | |
| nanometers | | | | | | | |
| (%) | | | | | | | |
| manufacturing | ◯ | ◯ | ◯ | X | X | X | X |
| method A | | | | | | | |
| dielectric constant | 3.23 | 2.62 | 2.40 | 2.29 | 1.97 | 2.10 | 1.81 |
| manufacturing | ◯ | ◯ | ◯ | ◯ | X | X | X |
| method B | | | | | | | |
| dielectric constant | 3.23 | 2.62 | 2.40 | 2.29 | 1.97 | 2.10 | 1.81 |

Table 1 shows that if the volume occupation ratio of the pores having a diameter greater than 0.6 nanometers is less than 30%, the diffusion of the metallic element can be suppressed certainly by any manufacturing method. Even when heat treatment of 400 degrees Centigrade is further carried out to the samples in which the diffusions are not found, the diffusions of the metallic elements into the interlayer insulation film 330 are not found. That is, it is shown that the diffusion of the metallic element into the interlayer insulation film 330 through the pores can be prevented effectively.

According to the embodiment, it is preferable to keep the volume occupation ratio of the pores having a diameter greater than 0.6 nanometers less than 30%, however, it is also preferable to incorporate the pores having a diameter greater than 0.6 nanometers to some extent.

By incorporating such larger pores into the interlayer insulation film, the stress applied by the interconnection layer may be alleviated. That is, the porous material used in the interlayer insulation film has a smaller thermal expansion coefficient than that of Cu (copper) used in the interconnection layers. Therefore, the interlayer insulation film is vulnerable to the thermal stress. The thermal stress can be more easily alleviated in the case where the larger pores are included than the case where uniform fine pores are distributed.

According to the result of the experiment performed by the Inventors, device failures caused by the thermal stress applied by the Cu (copper) interconnection layer has been effectively alleviated by incorporating pores having diameters larger than 0.6 nanometers have been reduced, and thus, it has turned out that interconnection structures with copper layers having a excellent reliability may be realized. In order to obtain the effect, it is preferable to incorporate pores having diameters larger than 0.6 nanometers into the interlayer insulation film to some extent, and it is more preferable to incorporate pores having diameters larger than 5 nanometers into the interlayer insulation film to some extent.

The embodiments of the present invention have been explained, referring to the examples and samples experimentally manufactured. However, the present invention is not limited to these specific examples.

For example, although the porous MSQ is mentioned as a material of the interlayer insulation film 220 in the examples, the invention is not limited to the example. Even if the present invention is applied to various insulating films, similar effect as the porous MSQ can be obtained. Especially, if the present invention is applied to the porous and low dielectric constant material, similar effect as the above-mentioned example can be obtained. In the invention, various kinds of insulating material including various kinds of silsesquioxane compounds, polyimide, fluorocarbon, parylene, and benzo cyclo butene can be used as a material of the interlayer insulation film 220.

The same effect is acquired even if the material containing Cu as the main ingredients used by semiconductor industry, such as a Cu—Sn alloy, a Cu—Ti alloy, and a Cu—Al alloy, other than Cu is used as a material of the interconnection layer 260. Further, the same effect is acquired also when other metallic material containing aluminum (Al), tungsten (W), etc. other than materials of Cu series as the main ingredients used by the semiconductor industry.

On the other hand, the same effect is acquired also when Tungsten Nitride (WN), a Titanium Nitride (TiN), Tungsten Carbon Nitride (WCN), a Titanium Silicon Nitride (TiSiN), tantalum (Ta) or multilayer laminated by any elements above-mentioned other than TaN is used as the material of the barrier metal layer 240.

Although the steps usually used in semiconductor industry, such as forming etching stopper, photolithography process, and cleaning before and after processings, is omitted for facilitation of explanation, it should go without saying that those steps are included.

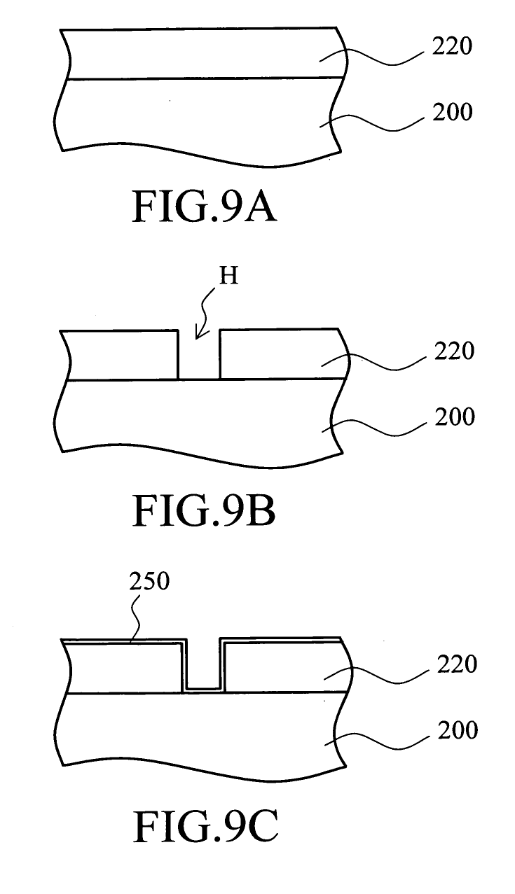

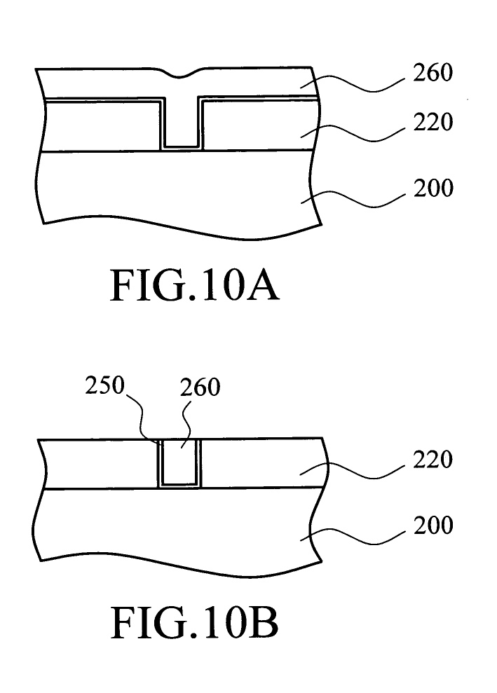

FIGS. 9A through 10B are cross-sectional views showing the processes of manufacturing method according to the modified examples of the present invention. The same symbols are given to the same elements as what were mentioned above with references to FIG. 1 through FIG. 8 about this figure, and detailed explanation will be omitted. In this modified example, the barrier metal layer 250 is formed in the process expressed in FIG. 9C by depositing TaN by atomic layer deposition method (ALD) or the atomic layer chemical vapor deposition method (ALCVD). If the barrier metal layer is formed by the ALD method as mentioned above, the diffusion into the porous and low dielectric constant film becomes remarkable compared with the PVD method. In contrast to this, according to the invention, by forming the porous interlayer insulation film 220 in which the volume occupation ratio of the pores having a diameter greater than 0.6 nanometers is less than 30%, the diffusion of the barrier metal can be prevented effectively. Thus, the barrier metal layer 250 can be formed using the ALD method.

By the ALD method, since it is possible to control thickness precisely, the ultra thin film can be formed. In this modified example, the barrier metal layer 250 which is the ultra thin film of 0.5 nanometer thickness can be formed. Consequently, the barrier metal layer having relatively higher resistance than an interconnection material, such as Cu can be formed as a thin film. Then, an interconnection resistance and a via resistance can be lowered without reducing integration density.

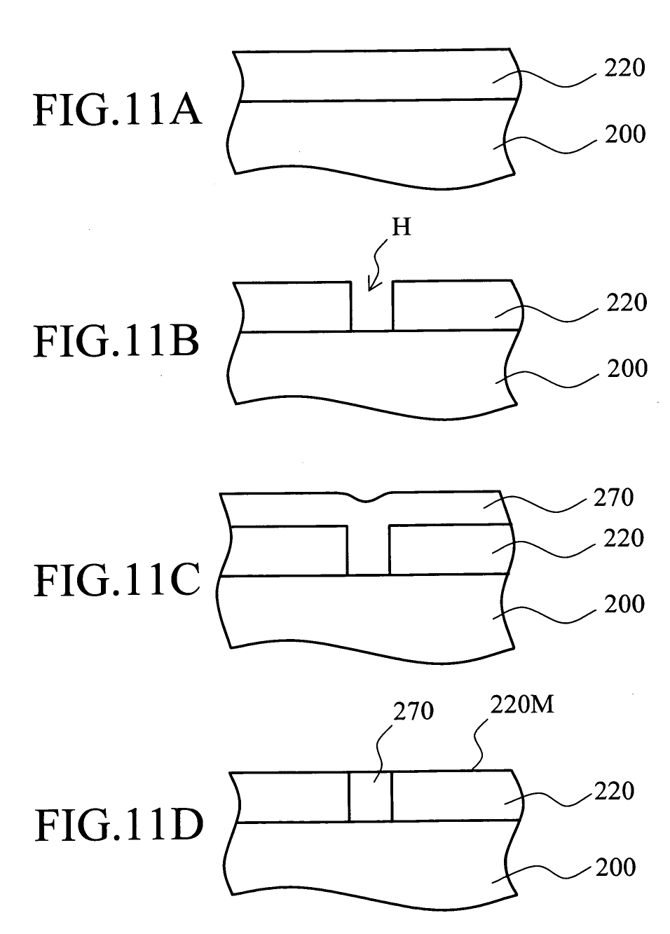

FIGS. 11A through 11D are cross-sectional views showing the processes of the manufacturing method according to the second modified example of the invention. The same symbols are given to the same elements as what were mentioned above with references to FIG. 1 through FIG. 10B about this figure, and detailed explanation will be omitted. In FIG. 11C, the interconnection layer 270 is formed by depositing tungsten (W) by the CVD method in this modified example. That is, the interconnection material is formed directly without the barrier metal layer. In FIG. 11D, an embedded structure can be obtained by removing the tungsten layer of the surface of the insulation film 220 by polishing using the CMP method can be obtained.

The interlayer insulation film consisting of the porous and low dielectric constant material is currently used corresponding to Cu interconnection in many cases. In the future, it is thought that the porous and low dielectric constant material is applied also to a tungsten (W) plug. According to the embodiment of the present invention, the diffusion of tungsten (W) can be prevented certainly and easily by forming the porous interlayer insulation film 220 in which the volume occupation ratio of the pores having a diameter greater than 0.6 nanometers is less than 30%.

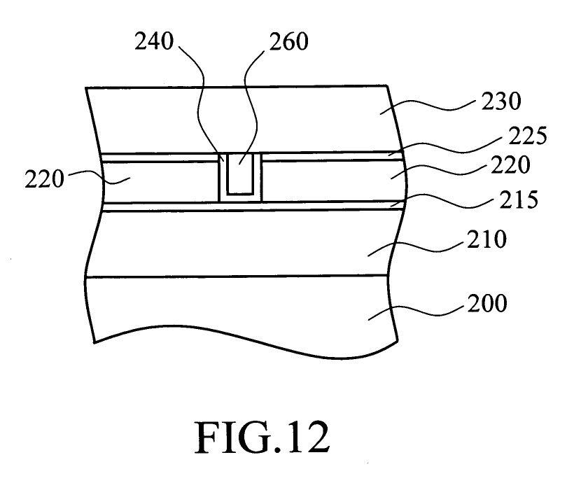

FIG. 12 is a schematic cross-sectional view illustrating a modified example of the semiconductor device according to the invention. The embedded metal may be provided on the insulation layer. In this modified example, the first interlayer insulation film 210, the hard mask 215, the second interlayer insulation film 220, and the protective film 230 are laminated in this order on the substrate 200 consisting of semiconductors, such as silicon. And the embedded metal of the barrier metal layer 240 and the metal interconnection layer 260 is formed in the second interlayer insulation film 220.

In such a semiconductor device, the diffusion of the metallic element constituting the barrier metal layer 240 and the metal interconnection layer 260 can be prevented effectively by forming the first interlayer insulation film 210 and the second interlayer insulation film 220 in a porous fashion in which the volume occupation ratio of the pores having a diameter greater than 0.6 nanometers is less than 30%. Therefore, the increase in a parasitic capacitance, degradation of an insulating characteristic, or degradation of a semiconductor element characteristic can be prevented.

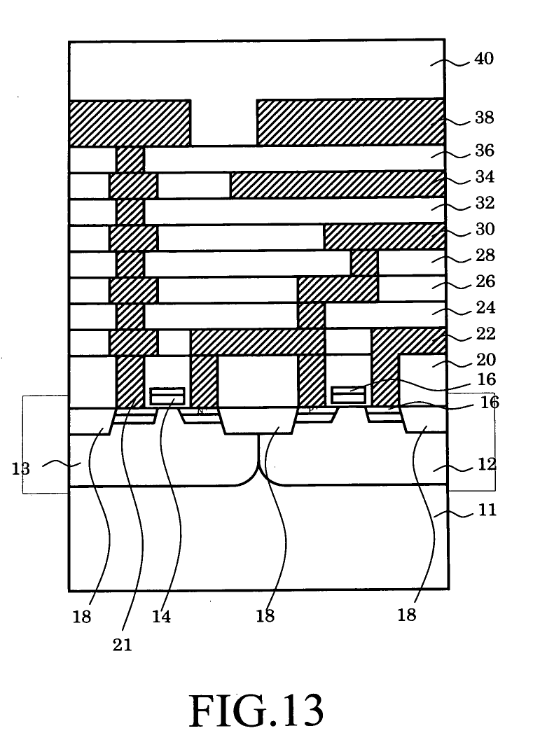

FIG. 13 is a schematic diagram illustrating the cross-sectional structure of an integrated circuit applied to the embodiment of the invention. That is, this semiconductor device is a logic device and has multilayer interconnection structure.

In this semiconductor device, the n-well 12 and the p-well 13 are formed on a silicon substrate 11 respectively, and the MOS transistors are formed on them. The transistors are covered with the first interlayer insulation film 20. Moreover, the silicides 16 are provided on the source, the drain and the gate 14 of the transistors as electrode contacts, respectively. The silicides 16 are connected to the first metal interconnection layer 22 provided on the contact holes through the Cu plug embedded in the contact holes opened in the first insulating interlayer film 20.

Multilayer interconnection structure is formed on the first metal interconnection layer 22. That is, the second interlayer insulation film 24, the second metal interconnection layer 26, the third interlayer insulation film 28, the third metal interconnection layer 30, the fourth interlayer insulation film 32, the fourth metal interconnection layer 34, the fifth interlayer insulation film 36, and the fifth metal interconnection layer 38 are laminated in this order on the first metal interconnection layer 22. The passivation film 40 is provided, thereon.

The via holes are opened appropriately in these interlayer insulation films. Each interconnection is perpendicularly connected by the embedded metal plug.

In the semiconductor device having multilayer interconnection structure, Cu has been used in order to reduce CR delay time in interconnection instead of aluminum (Al) which had been widely used. In general, Cu has lower resistivity and higher reliability.

In such a semiconductor device, by forming the first interlayer insulation film 210 and the second interlayer insulation film 220 in a porous fashion in which the volume occupation ratio of the pores having a diameter greater than 0.6 nanometers is less than 30%, the diffusion of the metal interconnection layers or the embedded plugs can be prevented effectively. Thus, the increase in a parasitic capacitance, degradation of an insulating characteristic, or characteristic degradation of a semiconductor element can be prevented.

Heretofore, the embodiments of the present invention have been explained, referring to the examples. However, the present invention is not limited to these specific examples.

For example, the substrate 200 provided under the interlayer insulation film 220 may have various kinds of semiconductor elements or structures other than what is illustrated in FIG. 13. Furthermore, thickness of the interlayer insulation film, and size, shape and number of the holes H can be appropriately selected as required in integrated circuits and various kinds of semiconductor elements.

Further, also concerning the semiconductor device according to the invention, those skilled in the art will be able to carry out the invention appropriately selecting a material or a structure within known techniques.

1. A semiconductor device comprising:
a semiconductor substrate; and
an interlayer interconnection structure provided on the semiconductor substrate including:
a porous insulation film in which a volume occupation ratio of pores of a diameter greater than 0.6 nanometers is less than 30%; and
a conductive part of a conductive material containing a metal as a major component.

2. The semiconductor device according to claim 1, wherein the conductive part is embedded in a hole provided in the insulation film.

3. The semiconductor device according to claim 1, wherein a barrier layer containing a conductive material of a higher resistivity than the conductive part is provided between the insulation film and the conductive part.

4. The semiconductor device according to claim 1, wherein the insulation film contains methyl silsequioxane.

5. The semiconductor device according to claim 1, wherein the conductive material of the conductive part contains copper as a major component.

6. The semiconductor device according to claim 1, wherein pores of a diameter greater than 0.6 nanometers are incorporated in the porous insulation film.

7. The semiconductor device according to claim 1, wherein pores of a diameter greater than 5 nanometers are incorporated in the porous insulation film.

8. A method for manufacturing a semiconductor device comprising:
forming a thin film containing a insulator material on a substrate;
opening a hole in the thin film; and
depositing a conductor material in the hole,
wherein the forming the thin film includes forming the thin film in a porous fashion in which a volume occupation ratio of pores of a diameter greater than 0.6 nanometers is less than 30%, having:
mixing a dielectric material and a pore generating material;
coating the mixture of the dielectric material and the pore generating material on the substrate;
drying the mixture; and
applying a heat treatment to the mixture.

9. The method for manufacturing a semiconductor device according to claim 8, wherein the dielectric material is methyl silsequioxane.

10. The method for manufacturing a semiconductor device according to claim 8, wherein the conductor material contains copper as a major component.

11. The method for manufacturing a semiconductor device according to claim 8, wherein pores of a diameter greater than 0.6 nanometers are formed in the forming the thin film.

12. The method for manufacturing a semiconductor device according to claim 8, further comprising depositing a barrier metal layer on a inner wall of the hole formed in the thin film, between the opening the hole and the depositing the conductor material.

13. A method for manufacturing a semiconductor device comprising:
forming a thin film containing a insulator material on a substrate;
opening a hole in the thin film; and
depositing a conductor material in the hole
wherein the forming the thin film includes forming the thin film in a porous fashion in which a volume occupation ratio of pores of a diameter greater than 0.6 nanometers is less than 30%, having:
coating a dielectric material containing pores on the substrate;
drying the dielectric material; and
applying a heat treatment to the dielectric material.

14. The method for manufacturing a semiconductor device according to claim 13, wherein the dielectric material is methyl silsequioxane.

15. The method for manufacturing a semiconductor device according to claim 13, wherein the conductor material contains copper as a major component.

16. The method for manufacturing a semiconductor device according to claim 13, wherein pores of a diameter greater than 0.6 nanometers are formed in the forming the thin film.

17. A method for manufacturing a semiconductor device comprising:
forming a thin film containing a insulator material on a substrate;
opening a hole in the thin film; and
depositing a conductor material in the hole
wherein the forming the thin film includes forming the thin film in a porous fashion in which a volume occupation ratio of pores of a diameter greater than 0.6 nanometers is less than 30%, having:
generating plasma of a gas containing a source gas of a dielectric material; and
decomposing the source gas by the plasma.

18. The method for manufacturing a semiconductor device according to claim 17, wherein the dielectric material is methyl silsequioxane.

19. The method for manufacturing a semiconductor device according to claim 17, wherein the conductor material contains copper as a major component.

20. The method for manufacturing a semiconductor device according to claim 17, wherein pores of a diameter greater than 0.6 nanometers are formed in the forming the thin film.
